(19) United States
(12) Patent Application Publication
(10) Pub. No.: US 2007/0200154 A1
(43) Pub. Date: Aug. 30, 2007

(54) SEMICONDUCTOR MEMORY DEVICE AND METHOD FOR MANUFACTURING SEMICONDUCTOR MEMORY DEVICE

(75) Inventor: Toshiyuki WASHIASHI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/678,791

(22) Filed: Feb. 26, 2007

(30) Foreign Application Priority Data
Feb. 28, 2006 (JP) 2006-052207

(51) Int. Cl. H01L 29/94

(52) U.S. Cl. 257/295

(57) ABSTRACT

A semiconductor memory device includes: a semiconductor substrate; a field effect transistor formed on the semiconductor substrate; a first interlayer dielectric layer formed on the field effect transistor; a first contact plug connected to the field effect transistor through the first interlayer dielectric layer; a ferroelectric capacitor disposed on the first interlayer dielectric layer and connected to the first contact plug; a second interlayer dielectric layer that is formed on the ferroelectric capacitor and includes a silicon nitride film at least in a portion thereof in a film thickness direction; a second contact plug connected to the ferroelectric capacitor through the second interlayer dielectric layer; and a wiring layer that is formed on the second interlayer dielectric layer and connected to the ferroelectric capacitor through the second contact plug.

The entire disclosure of Japanese Patent Application No. 2006-052207, filed Feb. 28, 2006 is expressly incorporated by reference herein.

### BACKGROUND

1. Technical Field

The present invention relates to semiconductor memory devices, and is particularly suitable when applied to methods for protecting ferroelectric capacitors from hydrogen.

2. Related Art

In order to miniaturize memory cells in a semiconductor memory device, a method in which ferroelectric capacitors are used in the memory cells may be adopted. Ferroelectric material is composed of Ferroelectric ceramic having oxygen atoms, and therefore is readily reduced in a hydrogen atmosphere. Ferroelectric material thus has a shortcoming by which characteristics of the ferroelectric capacitors would likely be deteriorated.

In this connection, for example, Japanese laid-open patent application JP-A-2003-68987 describes a method of forming an interlayer film on a memory cell capacitor to thereby alleviate a step difference at its edge section, and forming a hydrogen barrier film on the interlayer film, in an attempt to prevent deterioration of the characteristics by hydrogen and a reducing atmosphere and to compose a memory cell capacitor with excellent reliability.

However, if residual water is contained in the interlayer film, the residual water reacts with Ti in a wiring layer, whereby hydrogen is generated. For this reason, hydrogen penetrates into the ferroelectric capacitor through an opening section that is formed in the interlayer film to connect the ferroelectric capacitor to the wiring layer, which deteriorates the characteristics of the ferroelectric capacitor.

### SUMMARY

In accordance with an advantage of some aspects of the invention, it is possible to provide a semiconductor memory device having a ferroelectric capacitor, which is capable of protecting the ferroelectric capacitor from hydrogen even when an opening section is formed to connect the ferroelectric capacitor to a wiring layer, and a method for manufacturing such a semiconductor memory device.

In accordance with an embodiment of the invention, a semiconductor memory device includes: a semiconductor substrate; a field effect transistor formed on the semiconductor substrate; a first interlayer dielectric layer formed on the field effect transistor; a first contact plug connected to the field effect transistor through the first interlayer dielectric layer; a ferroelectric capacitor disposed on the first interlayer dielectric layer and connected to the first contact plug; a second interlayer dielectric layer that is formed on the ferroelectric capacitor and includes a silicon nitride film at least in a portion thereof in a film thickness direction; a second contact plug connected to the ferroelectric capacitor through the second interlayer dielectric layer; and a wiring layer that is formed on the second interlayer dielectric layer and connected to the ferroelectric capacitor through the second contact plug.

By this, the amount of moisture contained in the second interlayer dielectric layer on the ferroelectric capacitor can be reduced, and the second interlayer dielectric layer can be provided with hydrogen barrier capability. For this reason, the amount of hydrogen that may be generated as the second interlayer dielectric layer reacts with the wiring layer can be reduced, the amount of hydrogen that may penetrate into the ferroelectric capacitor can be reduced even when an opening section to connect the ferroelectric capacitor to the wiring is formed in the second interlayer dielectric layer, and deterioration of the characteristics of the ferroelectric capacitor by hydrogen and a reducing atmosphere can be suppressed.

Furthermore, in the semiconductor memory device in accordance with an aspect of the embodiment of the invention, the second interlayer dielectric layer may have a two-layer structure of silicon nitride film/silicon oxide film, a two-layer structure of silicon oxide film/silicon nitride film, a three-layer structure of silicon oxide film/silicon nitride film/silicon oxide film, or a three-layer structure of silicon nitride film/silicon oxide film/silicon nitride film.

By this, stresses can be alleviated, the amount of moisture contained in the second interlayer dielectric layer on the ferroelectric capacitor can be reduced, the second interlayer dielectric layer can be provided with hydrogen barrier capability, and deterioration of the characteristics of the ferroelectric capacitor can be suppressed.

In accordance with another embodiment of the invention, a semiconductor memory device includes: a semiconductor substrate; a field effect transistor formed on the semiconductor substrate; a first interlayer dielectric layer formed on the field effect transistor; a first contact plug connected to the field effect transistor through the first interlayer dielectric layer; a ferroelectric capacitor disposed on the first interlayer dielectric layer and connected to the first contact plug; a second interlayer dielectric layer formed on the ferroelectric capacitor; an opening section that is formed in the second interlayer dielectric layer and exposes a surface of the ferroelectric capacitor; a silicon nitride film that covers a side wall of the opening section and a surface of the second interlayer dielectric layer; a second contact plug connected to the ferroelectric capacitor through the opening section having the side wall covered by the silicon nitride film; and a wiring layer formed on the second interlayer dielectric layer and connected to the ferroelectric capacitor through the second contact plug.

By this, the side wall of the opening section formed in the second interlayer dielectric layer and the surface of the second interlayer dielectric layer are first covered by the silicon nitride film, and then the wiring layer can be formed on the second interlayer dielectric layer. For this reason, even when residual water remains in the second interlayer dielectric layer, the residual water can be prevented from contacting the wiring layer, and the amount of hydrogen that may be generated as the second interlayer dielectric layer reacts with the wiring layer can be reduced. As a result, even when an opening section for connecting the ferroelectric capacitor to the wiring layer is formed in the second interlayer dielectric layer, the amount of hydrogen that may penetrate into the ferroelectric capacitor can be reduced, and deterioration of the characteristics of the ferroelectric capacitor by hydrogen and a reducing atmosphere can be suppressed.

In accordance with another embodiment of the invention, a semiconductor memory device includes: a semiconductor substrate; a field effect transistor formed on the semiconductor substrate; a first interlayer dielectric layer formed on the field effect transistor; a first contact plug connected to the field effect transistor through the first interlayer dielectric layer; a ferroelectric capacitor disposed on the first interlayer dielectric layer and connected to the first contact plug; a second interlayer dielectric layer formed on the ferroelectric capacitor; a second contact plug connected to the ferroelectric capacitor through the second interlayer dielectric layer; and a wiring layer formed on the second interlayer dielectric layer and connected to the ferroelectric capacitor through the second contact plug, wherein the second contact plug is composed of Cu.

As a result, even when an opening section for connecting the ferroelectric capacitor to the wiring layer is formed in the second interlayer dielectric layer, the amount of hydrogen that may penetrate into the ferroelectric capacitor can be reduced, and deterioration of the characteristics of the ferroelectric capacitor by hydrogen and a reducing atmosphere can be suppressed.

Also, the semiconductor memory device in accordance with an aspect of the embodiment of the invention may be further equipped with a hydrogen barrier film that is formed between the ferroelectric capacitor and the second interlayer dielectric layer and covers the ferroelectric capacitor.

By this, the amount of moisture contained in the second interlayer dielectric layer on the ferroelectric capacitor can be reduced, the second interlayer dielectric layer can be provided with hydrogen barrier capability while the hydrogen barrier film can protect the ferroelectric capacitor from hydrogen, and deterioration of the characteristics of the ferroelectric capacitor by hydrogen and a reducing atmosphere can be suppressed.

In accordance with another embodiment of the invention, a method for manufacturing a semiconductor memory device includes the steps of: forming a field effect transistor formed on a semiconductor substrate; forming a first interlayer dielectric layer disposed on the field effect transistor over the semiconductor substrate; forming a first contact plug connected to the field effect transistor through the first interlayer dielectric layer; forming a ferroelectric capacitor disposed on the first interlayer dielectric layer and connected to the first contact plug; forming, on the ferroelectric capacitor, a second interlayer dielectric layer including a silicon nitride film in at least a portion thereof in a film thickness direction by a HDP-CVD method; forming a second contact plug connected to the ferroelectric capacitor through the second interlayer dielectric layer; and forming a wiring layer on the second interlayer dielectric layer and connected to the ferroelectric capacitor through the second contact plug.

By this, the amount of moisture and hydrogen contained in the second interlayer dielectric layer can be reduced, the second interlayer dielectric layer can be provided with hydrogen barrier capability, and deterioration of the characteristics of the ferroelectric capacitor by hydrogen and a reducing atmosphere can be suppressed.

### BRIEF DESCRIPTION OF THE DRAWINGS

FIGS. 1A-1C are cross-sectional views showing steps of a method for manufacturing a semiconductor memory device in accordance with a first embodiment of the invention.

FIGS. 2A-2C are cross-sectional views showing steps of the method for manufacturing a semiconductor memory device in accordance with the first embodiment of the invention.

FIGS. 3A-3C are cross-sectional views showing steps of a method for manufacturing a semiconductor memory device in accordance with another embodiment of the invention.

FIGS. 4A-4C are cross-sectional views showing steps of a method for manufacturing a semiconductor memory device in accordance with another embodiment of the invention.

### DESCRIPTION OF EXEMPLARY EMBODIMENTS

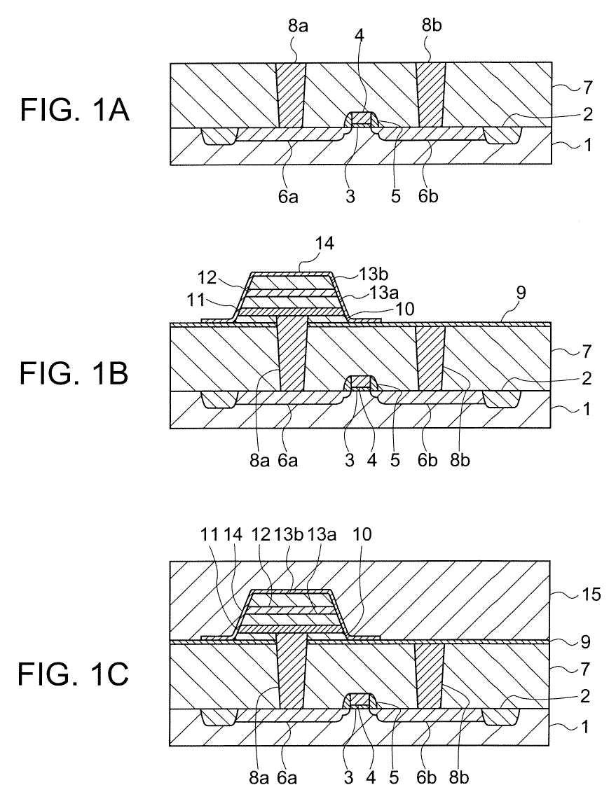

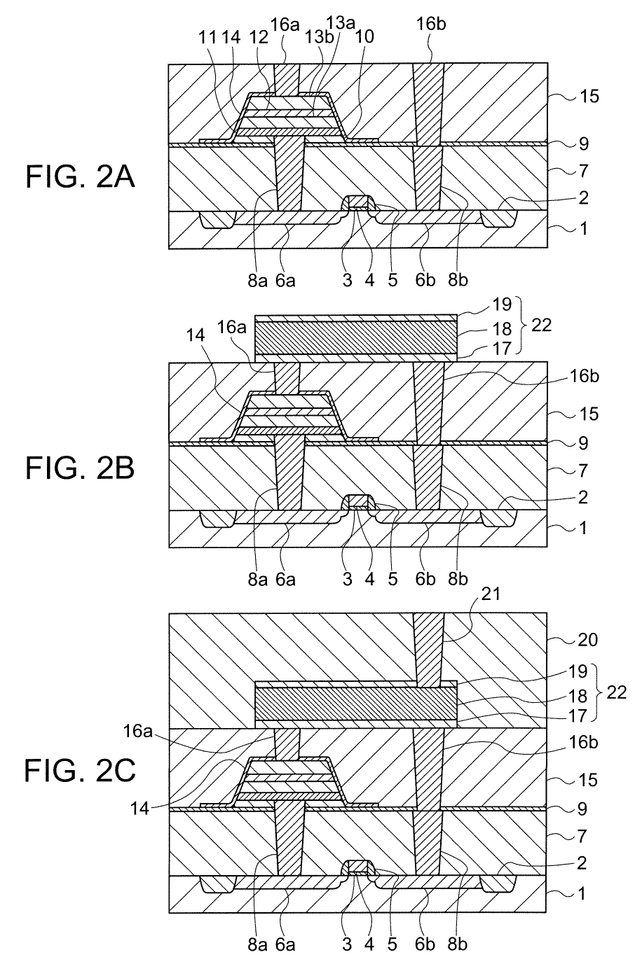

A semiconductor memory device and its manufacturing method in accordance with a preferred embodiment of the invention are described below with reference to the accompanying drawings. FIGS. 1A-1C and FIGS. 2A-2C are cross-sectional views showing a method for manufacturing a semiconductor memory device in accordance with a first embodiment of the invention.

As shown in FIG. 1A, a semiconductor substrate 1 includes an element isolation film 2 formed therein by an appropriate method such as a LOCOS (local oxidation of silicon) method. A gate electrode 4 is formed on the semiconductor substrate 1 through a gate dielectric film 3, and a sidewall 5 is formed on a side wall of the gate electrode 4. In the semiconductor substrate 1, source and drain layers 6a and 6b are formed on both sides of the gate electrode 4 through LDD layers, respectively. Further, an interlayer dielectric layer 7 is laminated over the gate electrode 3, and contact plugs 8a and 8b, which are connected to the source/drain layers 6a and 6b, respectively, are embedded in the interlayer dielectric layer 7.

The semiconductor substrate 1 may be composed of a material selected from, for example, Si, Ge, SiGe, SiC, SiSn, PbS, GaAs, InP, GaP, GaN and ZnSe. Also, as a material of the contact plugs 8a and 8b, for example, tungsten (W) may be used. As a material of the interlayer dielectric layer 7, a silicon oxide film may be used. Also, when forming the contact plugs 8a and 8b embedded in the interlayer dielectric layer 7, for example, a barrier metal film of a Ti/TiN structure may be intervened.

Next, as shown in FIG. 1B, a ferroelectric capacitor that is connected to the source layer 6a through the contact plug 8a is formed on the interlayer dielectric layer 7. Then, a hydrogen barrier film 14 that covers the ferroelectric capacitor is formed on the interlayer dielectric layer 7.

It is noted that the ferroelectric capacitor can have a laminated structure having a lower electrode 13a, a capacitance dielectric film 12 and an upper electrode 13b. Also, a barrier film 11 may be provided below the lower electrode 13a. It is noted that, as the barrier film 11, for example, TiAlN may be used; as the lower electrode 13a, for example, a laminated structure of Pt/IrOx/Ir may be used; as the capacitance dielectric film 12, for example, a ferroelectric film composed of PZT or the like may be used; and as the upper electrode 13a, for example, a laminated structure of Ir/IrOx/Pt may be used.

Also, a silicon nitride film 10 may be provided below the ferroelectric capacitor. It is noted that the silicon nitride film 10 may preferably be formed by high density plasma CVD with SiH₄—N₂ as a main raw material. By this, the amount of moisture and hydrogen contained in the silicon nitride film 10 can be reduced, such that deterioration of the characteristics of the ferroelectric capacitor by hydrogen and a reducing atmosphere can be suppressed. Furthermore, a hydrogen barrier film 9 may be provided below the ferroelectric capacitor. It is noted that, as the hydrogen barrier films 9 and 14, for example, AlO_{X} or TiO_{X} may be used.

Next, as shown in FIG. 1C, an interlayer dielectric layer 15 composed of a silicon nitride film formed on the ferroelectric capacitor by high density plasma CVD with SiH₄—N₂ as a main raw material. By this, the amount of moisture and hydrogen contained in the interlayer dielectric layer 15 can be reduced, such that deterioration of the characteristics of the ferroelectric capacitor by hydrogen and a reducing atmosphere can be suppressed.

Next, as shown in FIG. 2A, contact plugs 16a and 16b connected to the upper electrode 13b and the contact plug 8b, respectively, are embedded in the interlayer dielectric layer 15. It is noted that the contact plugs 16a and 16b may be formed with, for example, tungsten (W). Also, when forming the contact plugs 16a and 16b embedded in the interlayer dielectric layer 15, for example, a barrier metal film having a Ti/TiN structure may be intervened.

Next, as shown in FIG. 2B, for example, Ti, TiN, Al—Cu and TiN are successively sputtered in layers on the dielectric layer 15, and the laminated layers of Ti/TiN/Al—Cu/TiN are patterned by a photolithography technique and an etching technique, whereby a wiring layer 22 composed of a laminated structure of a Ti/TiN film 17, an Al—Cu film 18 and a TiN film 19 connected to the contact plugs 16a and 16b is formed on the interlayer dielectric layer 15.

It is noted that, as the wiring layer 22, for example, a TiN/Al—Cu/Ti/TiN structure, a TiN/Al/Ti/TiN structure, a TiN/Al—Cu/TiN structure, a TiN/Ti/Al/Ti/TiN structure, a Ti/TiN/Al—Cu/Ti/TiN structure, a Ti/TiN/Al/Ti/TiN structure, a Ti/TiN/Ti/Al—Cu/Ti/TiN structure, or a Ti/TiN/Ti/Al/Ti/TiN structure may be used, in addition to the Ti/TiN/Al—Cu/Ti/TiN structure described above.

Then, as shown in FIG. 2C, an interlayer dielectric layer 20 is formed on the wiring layer 22. Then, a contact plug 21 connected to the wiring 22 is embedded in the interlayer dielectric layer 20. It is noted that the contact plug 21 may be composed of, for example, tungsten (W). Also, when forming the contact plug 21 embedded in the interlayer dielectric layer 20, for example, a barrier metal film composed of a Ti/TiN structure may be intervened.

According to the above, the interlayer dielectric layer 15 on the ferroelectric capacitor can be composed of a silicon nitride film, the amount of moisture contained in the interlayer dielectric layer 15 can be reduced, and the interlayer dielectric layer 15 can be provided with hydrogen barrier capability.

As a result, the amount of hydrogen that may be generated by the reaction of the interlayer dielectric layer 15 with the wiring layer 22 can be reduced, the amount of hydrogen that may penetrate into the ferroelectric capacitor can be reduced even when an opening section to connect the ferroelectric capacitor to the wiring layer 22 is formed in the interlayer dielectric layer 15, and deterioration of the characteristics of the ferroelectric capacitor by hydrogen or a reducing atmosphere can be suppressed.

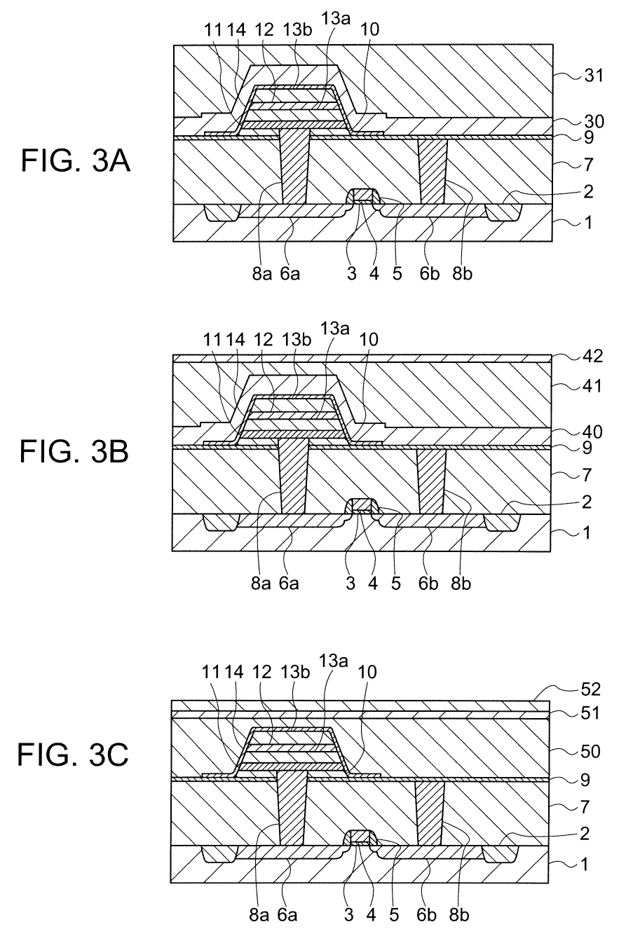

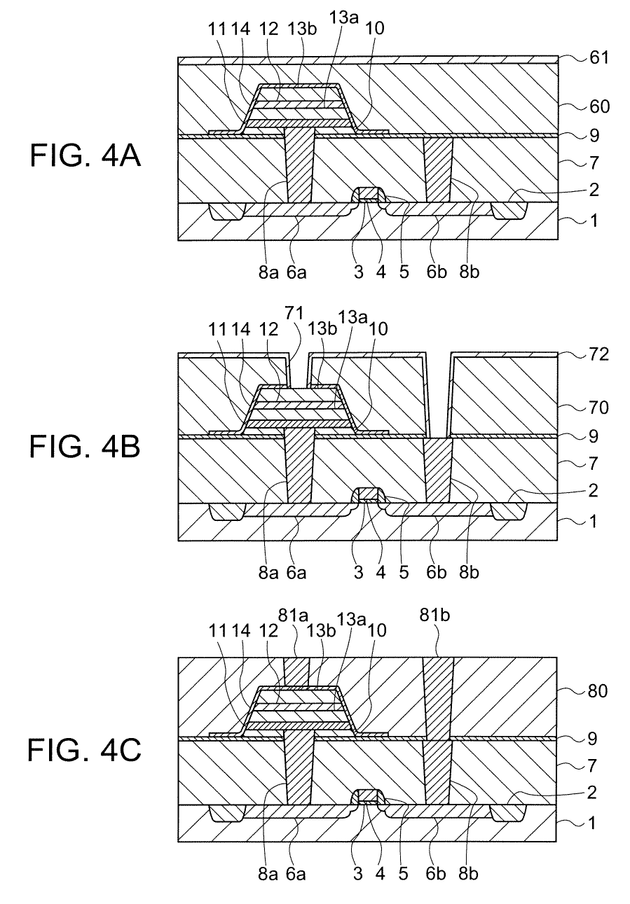

FIGS. 3A-3B and FIGS. 4A-4C are cross-sectional views showing methods for manufacturing a semiconductor memory device in accordance with other embodiments of the invention.

Instead of the interlayer dielectric layer 15 composed of a silicon nitride film described above with reference to FIG. 1C, an interlayer dielectric layer having a two-layer structure of a silicon nitride film 30 and a silicon oxide film 31 may be used, as shown in FIG. 3A.

Instead of the interlayer dielectric layer 15 composed of a silicon nitride film described above with reference to FIG. 1C, an interlayer dielectric layer having a three-layer structure of a silicon nitride film 40, a silicon oxide film 41 and a silicon nitride film 42 may be used, as shown in FIG. 3B.

Instead of the interlayer dielectric layer 15 composed of a silicon nitride film described above with reference to FIG. 1C, an interlayer dielectric layer having a three-layer structure of a silicon oxide film 50, a silicon nitride film 51 and a silicon oxide film 52 may be used, as shown in FIG. 3C.

Instead of the interlayer dielectric layer 15 composed of a silicon nitride film described above with reference to FIG. 1C, an interlayer dielectric layer having a two-layer structure of a silicon oxide film 60 and a silicon nitride film 61 may be used, as shown in FIG. 4A.

In this manner, instead of the interlayer dielectric layer 15 composed of a silicon nitride film shown in FIG. 1C, the interlayer dielectric layer may be composed of a multilayer structure including a silicon oxide film and a silicon nitride film, whereby stresses can be alleviated, the amount of moisture contained in the interlayer dielectric layer on the ferroelectric capacitor can be reduced, the interlayer dielectric layer can be provided with hydrogen barrier capability, and deterioration of the characteristics of the ferroelectric capacitor can be suppressed.

Referring to FIG. 4B, instead of the interlayer dielectric layer 15 composed of a silicon nitride film described above with reference to FIG. 1C, an interlayer dielectric layer composed of a silicon oxide film 70 is formed on the ferroelectric capacitor, an opening section 71 that exposes the upper electrode 13b is formed in the silicon oxide film 70, and then a silicon nitride film 72 may be formed by high density plasma CVD with SiH₄—N₂ as a main raw material in a manner to cover a sidewall of the opening section 71 and on a surface of the silicon oxide film 70. Then, after opening the silicon nitride film 71 to expose the upper electrode 13b, contact plugs 16a and 16b may be embedded.

By this, the side wall of the opening section 71 formed in the silicon oxide film 70 and the surface of the silicon oxide film 70 are first covered by the silicon nitride film 72, and then the wiring layer 22 can be formed on the silicon oxide film 70. For this reason, even when residual water remains in the silicon oxide film 70, the residual water can be prevented from contacting the wiring layer 22, and the amount of hydrogen that may be generated as the silicon oxide film 70 reacts with the wiring layer 22 can be reduced. As a result, even when the opening section 71 for connecting the ferroelectric capacitor to the wiring layer 22 is formed in the silicon oxide film 70, the amount of hydrogen that may penetrate into the ferroelectric capacitor can be reduced, and deterioration of the characteristics of the ferroelectric capacitor by hydrogen or a reducing atmosphere can be suppressed.

In any of the structures shown in FIGS. 3A-3C and FIGS. 4A-4C, Cu plugs may be embedded in the interlayer dielectric layer 15, as the contact plugs 16a and 16b shown in FIG. 2A. It is noted that, when Cu plugs are used as the contact plugs 16a and 16b, the Cu plugs can be formed by an electroplating method or the like.

By this, even when the opening sections for connecting the ferroelectric capacitor to the wiring layer 22 are formed in the interlayer dielectric layer 15, the contact plugs 16a and 16b can be formed without exposing the ferroelectric capacitor to a reducing atmosphere, and deterioration of the characteristics of the ferroelectric capacitor by hydrogen and a reducing atmosphere can be suppressed.

What is claimed is:

1. A semiconductor memory device comprising:
a semiconductor substrate;
a field effect transistor formed on the semiconductor substrate;
a first interlayer dielectric layer formed on the field effect transistor;
a first contact plug connected to the field effect transistor through the first interlayer dielectric layer;
a ferroelectric capacitor disposed on the first interlayer dielectric layer and connected to the first contact plug;
a second interlayer dielectric layer that is formed on the ferroelectric capacitor and includes a silicon nitride film at least in a portion thereof in a film thickness direction;
a second contact plug connected to the ferroelectric capacitor through the second interlayer dielectric layer; and
a wiring layer that is formed on the second interlayer dielectric layer and connected to the ferroelectric capacitor through the second contact plug.

2. A semiconductor memory device according to claim 1, wherein the second interlayer dielectric layer has one of a two-layer structure of silicon nitride film/silicon oxide film, a two-layer structure of silicon oxide film/silicon nitride film, a three-layer structure of silicon oxide film/silicon nitride film/silicon oxide film, and a three-layer structure of silicon nitride film/silicon oxide film/silicon nitride film.

3. A semiconductor memory device comprising:
a semiconductor substrate;
a field effect transistor formed on the semiconductor substrate;
a first interlayer dielectric layer formed on the field effect transistor;
a first contact plug connected to the field effect transistor through the first interlayer dielectric layer;
a ferroelectric capacitor disposed on the first interlayer dielectric layer and connected to the first contact plug;
a second interlayer dielectric layer formed on the ferroelectric capacitor;
an opening section that is formed in the second interlayer dielectric layer and exposes a surface of the ferroelectric capacitor;
a silicon nitride film that covers a side wall of the opening section and a surface of the second interlayer dielectric layer;
a second contact plug connected to the ferroelectric capacitor through the opening section having the side wall covered by the silicon nitride film; and
a wiring layer formed on the second interlayer dielectric layer and connected to the ferroelectric capacitor through the second contact plug.

4. A semiconductor memory device comprising:
a semiconductor substrate;
a field effect transistor formed on the semiconductor substrate;
a first interlayer dielectric layer formed on the field effect transistor;
a first contact plug connected to the field effect transistor through the first interlayer dielectric layer;
a ferroelectric capacitor disposed on the first interlayer dielectric layer and connected to the first contact plug;
a second interlayer dielectric layer formed on the ferroelectric capacitor;
a second contact plug connected to the ferroelectric capacitor through the second interlayer dielectric layer; and
a wiring layer formed on the second interlayer dielectric layer and connected to the ferroelectric capacitor through the second contact plug, wherein the second contact plug is composed of Cu.

5. A semiconductor memory device according to claim 1, further comprising a hydrogen barrier film that is formed between the ferroelectric capacitor and the second interlayer dielectric layer and covers the ferroelectric capacitor.

6. A method for manufacturing a semiconductor memory device includes the steps of:
forming a field effect transistor formed on a semiconductor substrate;
forming a first interlayer dielectric layer disposed on the field effect transistor over the semiconductor substrate;
forming a first contact plug connected to the field effect transistor through the first interlayer dielectric layer;
forming a ferroelectric capacitor disposed on the first interlayer dielectric layer and connected to the first contact plug;
forming, on the ferroelectric capacitor, a second interlayer dielectric layer including a silicon nitride film in at least a portion thereof in a film thickness direction by a HDP-CVD method;
forming a second contact plug connected to the ferroelectric capacitor through the second interlayer dielectric layer; and
forming a wiring layer on the second interlayer dielectric layer and connected to the ferroelectric capacitor through the second contact plug.
